(19) United States
(12) Patent Application Publication
(10) Pub. No.: US 2007/0075367 A1
(43) Pub. Date: Apr. 5, 2007

(54) SOI semiconductor component with increased dielectric strength

(76) Inventors: Remigiusz Viktor Boguszewics, Essen (DE); Ralf Rudolf, Dresden (DE)

Correspondence Address: BAKER BOTTS, L.L.P., 98 SAN JACINTO BLVD., SUITE 1500, AUSTIN, TX, 78701-4039, US

(21) Appl. No.: 11/462,161

(22) Filed: Aug. 3, 2006

(30) Foreign Application Priority Data
Feb. 6, 2004 (DE) 10 2004 006 002.9
Jan. 28, 2005 (WO) PCT/EP05/00839

(51) Int. Cl. H01L 27/12; H01L 27/01

(52) U.S. Cl. 257/347

(57) ABSTRACT

An SOI semi-conductor element has field electrodes and/or field zones which are arranged between a first and a second semi-conductor zone. Electric coupling is possible between the field electrodes and the field zones.

### CROSS-REFERENCE TO RELATED APPLICATIONS

This application is a continuation of co-pending International application Ser. No. PCT/EP2005/000839 filed Jan. 28, 2005, which designates the U.S., and claims priority to German application number 10 2004 006 002.9 filed Feb. 6, 2004.

### TECHNICAL FIELD

The present invention relates to an SOI semiconductor component.

### BACKGROUND

SOI (silicon on insulator) semiconductor components are characterized by a semiconductor layer arranged on an insulator layer, in which semiconductor layer, diodes, transistors or comparable semiconductor components can be implemented.

In SOI semiconductor components, it is generally of interest to achieve the highest possible reverse-voltage strength.

In the context of the present application, the abbreviation “SOI” is used synonymously for components having a semiconductor layer, an insulation layer and a further semiconductor layer of any materials, which has become established in technical language so that not only components of silicon but of any semiconductor materials such as, for example, germanium or gallium arsenide are meant by this.

DE 101 06 359 C1 describes a lateral SOI semiconductor component in thin film technology with one anode contact and one cathode contact, the anode contact and the cathode contact in each case being located above separate shield regions of the substrate, i.e. above regions which are doped complementary to the basic doping of the substrate. Furthermore, the anode contact is electrically connected to the substrate, as a result of which the space charge zone is transferred to the substrate and removed in the substrate. As a further measure for removing the space charge zone in the substrate, floating field rings, i.e. field rings which are not at a defined potential, are used there which are arranged between the shield regions.

FIG. 1 shows a section of an SOI semiconductor component constructed as MOS transistor according to the prior art. The SOI semiconductor component is essentially constructed in layers. On a semiconductor substrate 10 with a metallization 15, a first insulator layer 20 followed by a semiconductor layer 30 is arranged on a side facing away from the metallization 15. The insulator layer 20 is also called a buried insulator since it is “buried” underneath the semiconductor layer 30. On the side of the semiconductor layer 30 opposite to the first insulator layer 20, a second insulator layer 40 is arranged. In the semiconductor layer 30, a first semiconductor zone 31 forming the source zone and, spaced apart from this, a second semiconductor zone 32 forming the drain zone is arranged, which are in each case contacted by contacts 51 and 52, respectively.

The first semiconductor zone 31 is followed in the semiconductor layer 30 by a channel zone 33 with complementary doping, a drift zone 30a which is of the same type of conduction as the first 31 and second semiconductor zone but doped weaker, being formed between this channel zone 33 and the second semiconductor zone 32. A gate electrode 41 which is embedded in the second insulator layer 40 above the semiconductor layer 30 is used for controlling a conducting channel in the channel zone 33. A necessary terminal for external contacting of the gate electrode 41 is not shown.

The sandwich-like structure of the first 20 and second 40 insulator layer and the intermediate semiconductor layer 30 is arranged on the semiconductor substrate 10 which is, for example, of the same type of conduction as the first 31 and second 32 semiconductor zone or the drift zone 30a, respectively.

The semiconductor substrate 10 has on its side facing the first insulator layer 20 shield zones 11, 12 with complementary doping to the semiconductor substrate 10, and field zones 13a, 13b of the same type of conduction as the semiconductor substrate 10. A contact terminal 51 of the first semiconductor zone 31 is also electrically conductively connected to the shield zone 11 in addition to the first semiconductor zone 31.

From DE 197 55 868 C1, a high-voltage SOI thin film transistor is known which has a field plate, arranged between a gate electrode and a drain zone, which is connected to the zones arranged in the semiconductor thin layer with complementary doping to the latter.

SOI semiconductor components of the above type have the disadvantage that the voltage present in the reverse state at the buried insulator layer can lead to voltage breakdowns, as a result of which the insulator layer, and thus the SOI semiconductor component, could be destroyed.

### SUMMARY

An SOI semiconductor component may comprise a layered structure which successively comprises a semiconductor substrate, a first insulator layer and a semiconductor layer and further may comprise a first semiconductor zone and a second semiconductor zone which are arranged laterally spaced apart from one another in the semiconductor layer, and a third semiconductor zone arranged between the first and second semiconductor zone, a fourth semiconductor zone which is arranged in the semiconductor substrate, at least one field zone which is arranged between the first and second semiconductor zone in the lateral direction in the semiconductor substrate and has complementary doping to the fourth semiconductor zone, and at least one field electrode which is arranged between the first and second semiconductor zone in the lateral direction on the side of the semiconductor layer facing away from the first insulator layer.

### BRIEF DESCRIPTION OF THE DRAWINGS

In the text which follows, exemplary embodiments of the invention will be explained in greater detail with reference to the drawings, in which:

FIG. 1 shows a section of an SOI semiconductor component of the prior art in cross section,

FIG. 2a shows a section of an SOI semiconductor component according to an embodiment with field electrodes, in cross section,

FIG. 2b shows a top view of the SOI semiconductor component according to an embodiment according to FIG. 2a,

FIG. 2c shows a cross section through the semiconductor layer of the SOI semiconductor component according to FIG. 2a,

FIG. 2d shows a section through the semiconductor substrate in the area of the shield or field zone according to FIG. 2a,

FIG. 3a shows a section, analogous to FIG. 2a, of an SOI semiconductor component according to an embodiment with field electrodes, the field electrodes being contacted not only with the semiconductor layer but also with the semiconductor substrate, in cross section,

FIG. 3b shows a top view of the SOI semiconductor component according to an embodiment according to FIG. 3a,

FIG. 3c shows a cross section through the semiconductor layer of the SOI semiconductor component according to FIG. 3a,

FIG. 3d shows a section through the semiconductor substrate in the area of the shield or field zone according to FIG. 3a,

FIG. 4a shows a section, analogous to FIGS. 2a and 3a, of an SOI semiconductor component according to an embodiment, the field electrodes being electrically conductively connected to the semiconductor substrate and being insulated with respect to the semiconductor layer, in cross section,

FIG. 4b shows a top view of the SOI semiconductor component according to an embodiment according to FIG. 4a,

FIG. 4c shows a cross section through the semiconductor layer of the SOI semiconductor component according to FIG. 4a,

FIG. 4d shows a section through the semiconductor substrate in the area of the shield or field zone according to FIG. 4a,

FIG. 5a shows a section through the semiconductor layer according to FIG. 2c with compensation zones arranged between two adjacent coupling points,

FIG. 5b shows a section through the semiconductor layer according to FIG. 3c with compensation zones arranged between two adjacent coupling points,

FIG. 5c shows a section through the semiconductor layer according to FIG. 4c with compensation zones arranged between two adjacent coupling points,

FIG. 6a shows a section of an SOI semiconductor component according to an embodiment in the area of the compensation zones according to FIGS. 2a, 3a, 5a, 5b, in cross section,

FIG. 6b shows a section of an SOI semiconductor component according to an embodiment in the area of compensation zones according to FIGS. 4a and 5c, in cross section,

FIG. 7 shows a broken section of an SOI semiconductor component according to an embodiment according to FIGS. 2a, 2c, 3a, 3c, 5a, 5b, in a perspective view,

FIG. 8 shows a section of an SOI semiconductor component according to an embodiment with a parasitic MOS transistor and a channel stopper zone,

FIG. 9a shows a section through an SOI semiconductor component according to FIGS. 3a-d with a zener diode structure,

FIG. 9b shows the SOI semiconductor component according to FIG. 9a in cross section,

FIG. 10a shows an SOI semiconductor component according to FIGS. 2a-d with a zener diode structure of cascaded zener diodes,

FIG. 10b shows a section through the SOI semiconductor component according to FIG. 10a in the area of the zener diodes.

In the figures, identical reference symbols designate identical parts having the same meaning.

### DETAILED DESCRIPTION

An SOI semiconductor component may have a layered structure and may comprise successively a semiconductor substrate, a first insulator layer and a semiconductor layer. In the semiconductor layer, a first and a second semiconductor zone can be arranged laterally spaced apart from one another. Between the first and the second semiconductor zone, the semiconductor layer may have a third semiconductor zone. In the lateral direction between the first and the second semiconductor zone, a field zone with complementary doping to a fourth semiconductor zone also arranged in the semiconductor substrate can be arranged in the semiconductor substrate. Furthermore, at least one field electrode can be arranged between the first and second semiconductor zone above the side of the semiconductor layer facing away from the first insulator layer.

As a rule, the first and second semiconductor zone may have higher doping than the semiconductor layer.

The SOI semiconductor component according to an embodiment can preferably be constructed as a diode or field-effect transistor.

In the case of a diode, the first semiconductor zone forms the p-doped anode and the second semiconductor zone forms the n-doped cathode.

In the case of a field-effect transistor, the first semiconductor zone correspondingly forms the source zone and the second semiconductor zone forms the drain zone. In this arrangement, both semiconductor zones have the same type of conduction. In addition, a fifth semiconductor zone channel zone is arranged between the first and the third semiconductor zone which forms the channel zone.

Furthermore, it may be provided to transfer the space charge zone into the semiconductor substrate. Such an embodiment may require a connection between the semiconductor layer and the semiconductor substrate. To implement such connections, electrical conductors such as, for example, metals, but also resistors, diodes, transistors, etc. can be used.

Such connections may preferably be implemented between the semiconductor substrate and the source and/or drain zone. According to a preferred embodiment, the first and/or the second semiconductor zone can be connected to the semiconductor substrate.

Homogenization of the electrical field occurring in the SOI semiconductor component can be achieved by in each case one shield zone opposite to the first and second semiconductor zone, respectively, and arranged in the semiconductor substrate and having complementary doping with respect to the latter. The connection of the semiconductor substrate to the first and/or second semiconductor zone, described above, can be preferably effected at these shield zones.

In the semiconductor substrate underneath the first insulator layer, at least one field zone with complementary doping to the semiconductor substrate and which extends starting from the boundary face between the semiconductor substrate and the first insulator layer into the volume area of the semiconductor substrate, can be arranged in the lateral direction between the first and second semiconductor zone. If the semiconductor substrate has shield zones allocated to the first and second semiconductor zone, the field zones are arranged between these shield zones.

Field zones are areas arranged on the top or boundary face of the semiconductor substrate and having complementary doping to the fourth semiconductor zone. They can be produced by known methods such as alloying, diffusion, ion implantation, epitaxial growth or the like.

The field zones are preferably arranged to be floating, i.e. they are not at any electrical potential predetermined, for example, by an external terminal. In floating field zones, their electrical potential only results from the distribution of the electrical field in the SOI semiconductor component.

Furthermore, at least one field electrode can be arranged in the lateral direction between the first and second semiconductor zone on the side of the semiconductor layer facing away from the first insulator layer.

The at least one field electrode may consist of conductive material such as, for example, n⁺-doped polysilicon or of metal, e.g. aluminum. It has any shape but it can preferably be constructed to be approximately stepped or as an inclined plate. Various widths, inclinations and distances from the semiconductor layer are also possible.

The at least one field electrode may be advantageously electrically insulated from the semiconductor layer. In one embodiment, this insulation can be effected by means of a further insulator layer which is arranged between the semiconductor layer and the field electrodes.

Using field zones in conjunction with field electrodes leads to homogenization of the electrical field building up, in particular, in the reverse state of the SOI semiconductor component. This is equivalent to an increase in the insulation strength since the spatial change in the electrical field is a measure of the potential difference between two points. In SOI semiconductor components, the insulator layer arranged between the semiconductor layer and the semiconductor substrate, in particular, is at risk due to voltage breakdowns. Although it is possible in principle to increase the insulation strength also by increasing the insulator layer thickness, this entails production disadvantages. One field electrode and one field zone may be preferably opposite one another in pairs in each case.

The principle according to the embodiments can be generally transferred to all SOI semiconductor components.

A further improvement in the above-mentioned arrangement in the sense of homogenizing the electrical field in the SOI semiconductor component can be achieved by coupling a field electrode to the semiconductor layer and/or a field zone. This coupling may preferably be achieved by introducing coupling points, a distinction being made between three different types. In the case of type I, the relevant field electrode can be electrically conductively connected only to the semiconductor layer and in type II it can be additionally electrically conductively connected to a field zone. In type III, in contrast, the field electrode can be electrically conductively connected to a field zone but not to the semiconductor layer. In type III, the field electrode may be preferably electrically insulated with respect to the semiconductor layer.

In one embodiment, the coupling points of type I or II may have contacting zones of the second type of conduction complementary to the third semiconductor zone, which connect the third semiconductor zone to the field electrode. The contacting zones in a particularly preferred manner may comprise a first and a second area, the first area having higher doping than the second area and the first area being contacted with the field electrode and the second area being contacted with the third semiconductor zone.

An SOI semiconductor component according to an embodiment may preferably have coupling points of exactly one of the three types mentioned. In general, however, any combination of coupling points of different type and different number is possible.

Introducing the coupling points, especially when the third semiconductor zone has contacting zones or insulations in the area of the coupling points, reduces the cross section of the third semiconductor zone available for the current flow through the SOI semiconductor component, which increases the resistance of the component.

To compensate for this disadvantage, the introduction of compensation zones can be provided which are characterized by the fact that the doping of the third semiconductor zone is raised between two adjacent coupling points so that the conductivity is increased in these zones. Such compensation zones may be preferably arranged between two coupling points of the same field electrode. The width of the compensation zones depends on their doping concentration, the layer thicknesses of the second insulator layer and of the semiconductor layer, respectively, and the width of the field zones and of the field electrodes, respectively. With a suitable selection of parameters, low drift zones resistances can be achieved, the blocking capability remaining the same.

Introducing field and/or shield zones may form a parasitic MOS transistor, the gate of which is formed by the drift zone located in the semiconductor layer, between two adjacent such zones in conjunction with the intermediate volume area of the semiconductor substrate with complementary doping to these zones. The parasitic MOS transistor is biased into conduction with increasing current flow in the drift zone.

To prevent this effect, the introduction of a channel stopper zone can be provided which is arranged between a field zone and a further field zone or, respectively, between a field zone and a shield zone in the semiconductor substrate, has the type of conduction of the fourth semiconductor zone but has higher doping than the latter. This may raise the threshold voltage of the parasitic MOS transistor. The channel stopper zone can preferably be formed continuously between two adjacent field zones or, respectively, between a field zone and a shield zone.

If an SOI semiconductor component with field zones and/or field electrodes is in the reverse state, these field zones or field electrodes may become charged. If the reverse voltage applied is then switched off or at least greatly reduced, the field zones or field electrodes take relatively long to discharge. During this discharging time, the field zones or field electrodes still charged up act like a gate which has the effect that the SOI semiconductor component remains in the reverse state for some time which reduces the switching speed of the component.

According to an embodiment, it is provided, therefore, to limit the voltage present between the semiconductor layer and a field zone or a field electrode, respectively, and thus its charge.

This can be advantageously done by a zener diode structure arranged between the semiconductor layer and a field zone or a field electrode, respectively, of one or more cascaded zener diodes. A zener diode may consist of a pn junction with high doping of the mutually complementary semiconductor areas. Depending on the layer thickness of the semiconductor junction, the strength of the doping and the concentration gradient of the dopants in the junction area, the zener diode may have a breakdown voltage, at the transgression of which it changes into the conducting state so that the voltage applied is removed and limited to the breakdown voltage.

In general, a zener diode structure may consist of a sequence of at least two semiconductor areas with high doping, two successive semiconductor areas having complementary doping. A zener diode structure may have two terminal areas which consist of the first and the last of all successive semiconductor areas.

The zener diode structure can be interconnected in the SOI semiconductor component in such a manner that the one terminal area may contact the third semiconductor zone and the other one may contact the field electrode or field zone, respectively. For production reasons, the zener diode structure can preferably be arranged in the semiconductor layer. It may be necessary to provide the zener diode structure with insulation area by area, particularly with respect to the semiconductor layer.

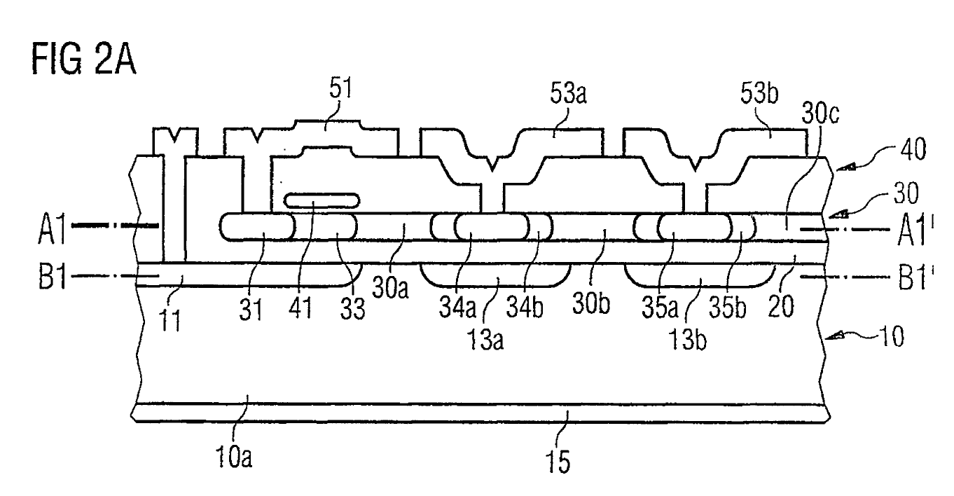

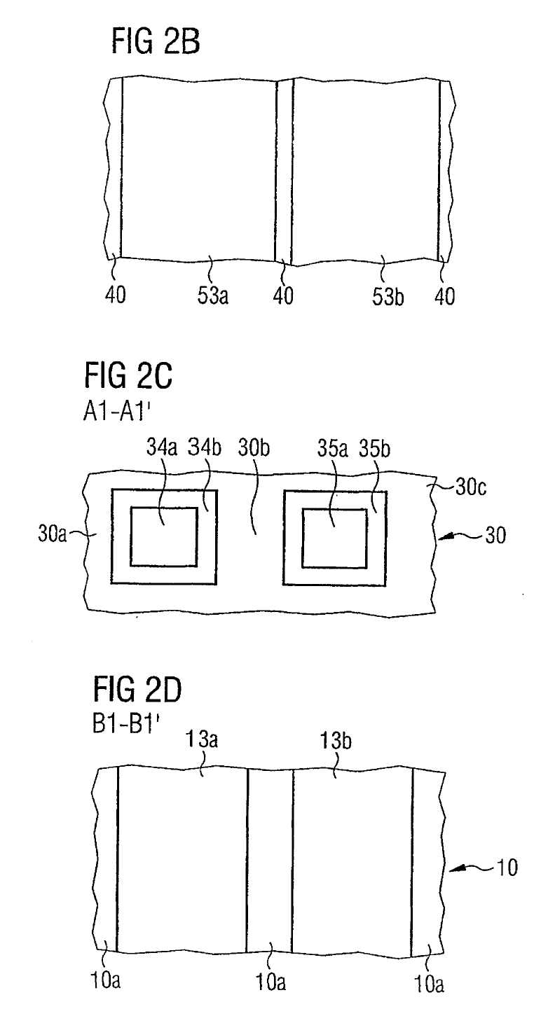

FIG. 2a shows a section of a lateral SOI semiconductor component according to an embodiment, constructed as MOSFET, in cross section.

The structure of the component is layered and consists of a semiconductor substrate 10 with an optional metallization 15 on which a first insulator layer 20 is arranged followed by a semiconductor layer 30 and a second insulator layer 40.

The semiconductor layer 30 has an n⁺-doped first semiconductor zone 31, connected to a contact 51, which forms a source zone. This is followed by a p⁻-doped fifth semiconductor zone 33, also arranged in the semiconductor layer 30, which is formed as channel zone, and an n⁻-doped third semiconductor zone. This is formed as a coherent region—which cannot be seen in the present sectional view—and consists of a number of part-regions, the part-regions 30a, 30b, 30c of which are shown by way of example.

A second semiconductor zone following the third semiconductor zone and formed as n⁺-doped drain zone, and a contact connected thereto, are not shown.

In the area of its boundary face to the first insulator layer 20, the semiconductor substrate 10 has a p-doped shield zone 11 and two floating field zones 13a, 13b. Opposite each field zone 13a, 13b, a field electrode 53a, 53b allocated to the former is located with respect to the semiconductor layer 30. The field electrodes have a stepped structure but, for example, inclined field electrodes 53a, 53b are also possible.

In general, the individual field electrodes 53a, 53b of an SOI semiconductor component could also be formed differently. In particular, they could differ in their arrangement with respect to width, inclination, shape and material. The field electrodes 53a, 53b, similarly to the field zones 13a, 13b, have an elongated form perpendicular to the plane of the drawing, but an annular configuration can also be selected.

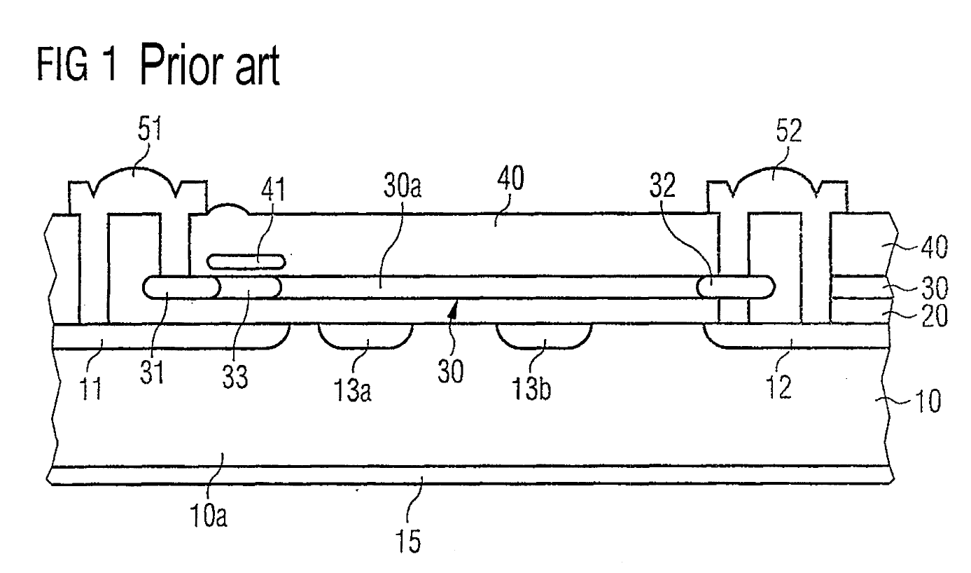

The area of the second semiconductor zone, not shown, can be arranged analogously to the semiconductor zone provided with reference symbol 32 in FIG. 1, wherein the associated contact, corresponding to contact 52 in FIG. 1, can be optionally electrically contacted only with the second semiconductor zone or additionally with the semiconductor substrate. In the case of contacting with the semiconductor substrate, this is preferably done in the area of a p-doped shield zone 12 arranged underneath the second semiconductor zone in the edge area of the semiconductor substrate.

Similarly to the field zones 13a, 13b, the field electrodes 53a, 53b have an elongated shape, which cannot be detected in FIG. 2a, extending perpendicularly to the plane of the drawing. At individual points, the field electrodes 53a, 53b are provided with coupling points of type I, spaced apart from one another in the longitudinal direction of the field electrodes 53a, 53b, at which coupling points they are capacitively coupled to their associated field zone 13a and 13b, respectively, and to the third semiconductor zone 30a, 30b, 30c via contacting zones 34, 35.

In the area of each coupling point, the third semiconductor zone 30a, 30b, 30c is provided with a contacting zone 34, 35 with complementary doping to the latter, wherein each of the contacting zones 34, 35 is in each case formed from an inner contacting zone 34a, 35a and an outer contacting zone 34b, 35b. The inner contacting zones 34a, 35a are contacted with the field electrodes 53a, 53b and doped higher—p⁺-doped in the present example—than the outer contacting zones 34b, 35b which are in contact with the third semiconductor zone 30a, 30b, 30c.

FIG. 2b shows a top view of the area of the field electrode 53a, 53b according to FIG. 2a. The field electrodes 53a, 53b extend in parallel with one another and are arranged on the second insulator layer 40.

FIG. 2c shows a section through the semiconductor layer in the plane A1-A1′ according to FIG. 2a. In the semiconductor layer 30, the two contacting zones 34, 35 are arranged with their inner contacting zones 34a, 35a and outer contacting zones 34b, 35b. In each case one of the inner contacting zones 34a, 35a is enclosed by an outer contacting zone 34b, 35b.

FIG. 2d shows a section through the semiconductor substrate 10 at the level of the shield zone 11 and of the field zones 13a, 13b in plane B1-B1′ according to FIG. 2a. Two floating field zones 13a, 13b are arranged in the semiconductor substrate 10. The field zones 13a, 13b can be produced by any doping method, for example by thermal diffusion.

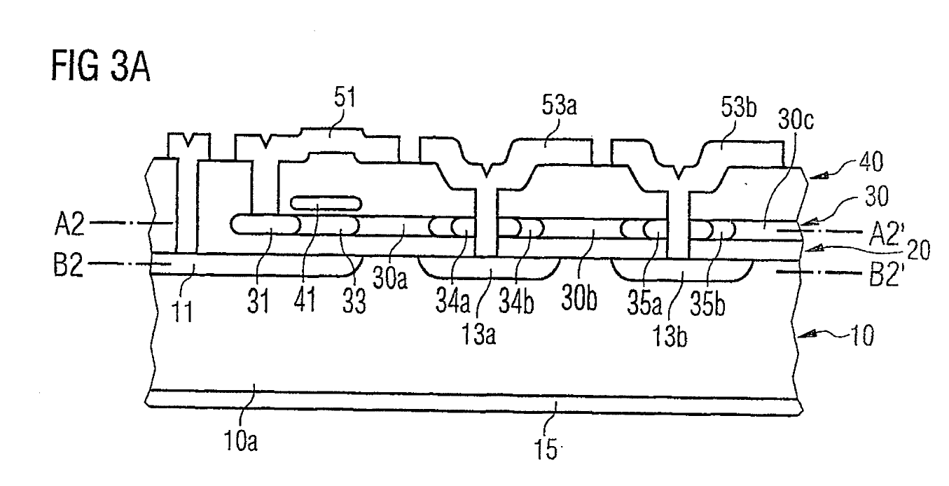

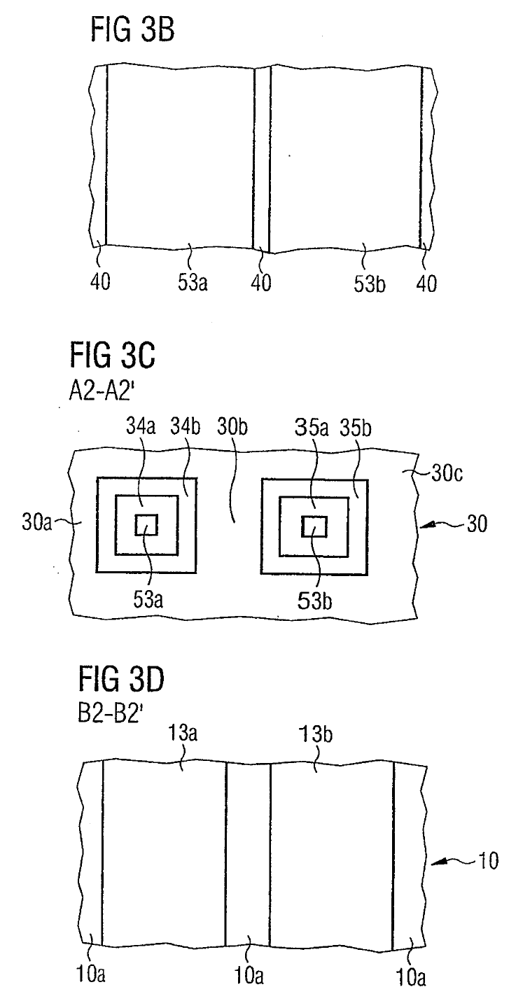

Another possibility of coupling between field zones 13a, 13b and their in each case associated field electrodes 53a, 53b is shown in FIG. 3a. The field electrodes 53a, 53b are here connected to their associated field zone 13a, 13b, on the one hand, and to the third semiconductor zone 30a, 30b, 30c via an inner 34a, 35a and an outer 34b, 35b contacting zone at type II coupling points. As a result, the electrical potential of in each case one field zone 13a, 13b and its associated field electrode 53a, 53b is aligned.

FIG. 3b shows a top view of the component according to FIG. 3a which corresponds to the view of FIG. 2a.

FIG. 3c shows a sectional view through the semiconductor layer 30 in the area of two type III coupling points in plane A2-A2′ from FIG. 3a, which shows that the field electrodes 53a, 53b are brought through the third semiconductor zone 30a, 30b at the coupling points. Here, too, the field electrodes 53a, 53b are connected to the third semiconductor zone 30a, 30b, 30c by means of an inner 34a, 35a and an outer 34b, 35b contacting zone.

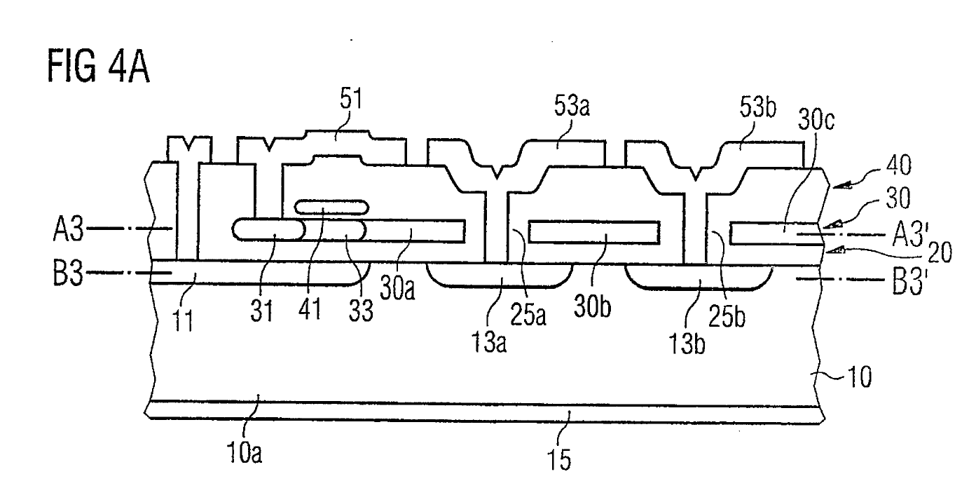

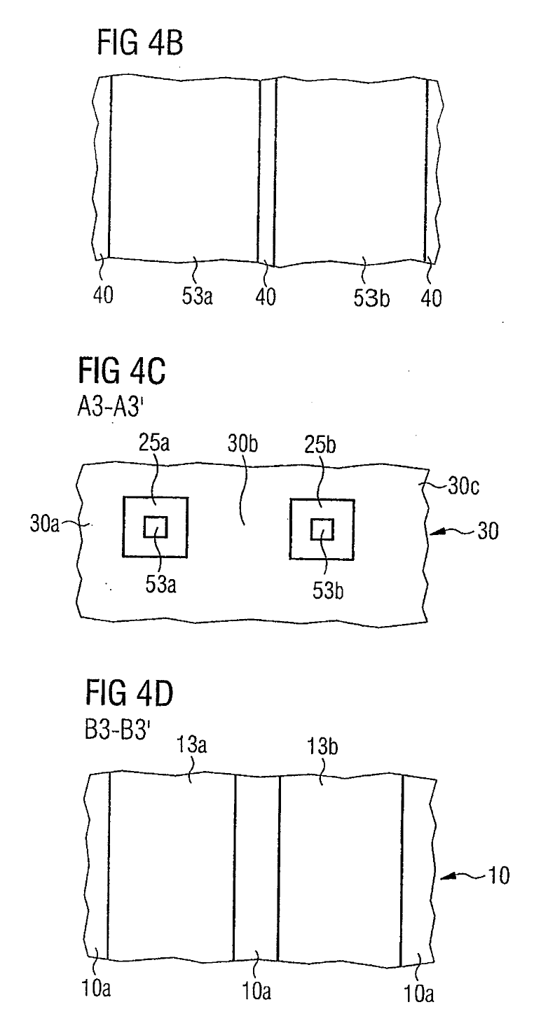

A further possibility for coupling in each case one field electrode 53a, 53b and a field zone 13a, 13b associated with it is shown in FIG. 4a. Here, too, similarly to FIG. 3a, the field electrode 53a, 53b is electrically connected to its associated field zone 13a, 13b at the coupling points. Unlike the component according to FIG. 3a, however, the field electrodes 53a, 53b in the semiconductor layer 30 are insulated from the semiconductor layer 30 by an insulation. Each pair formed from a field electrode 53a, 53b and its associated field zone 13a, 13b is arranged to be electrically floating.

FIG. 4b shows a top view of a section of the semiconductor element according to FIG. 4a with the second insulator layer 40 and the field electrodes 53a, 53b arranged thereupon.

FIG. 4c shows a section through the semiconductor layer 30 of FIG. 4a in plane A3-A3′. From this view, the significant difference from the components according to FIGS. 2 and 3 can be seen. It relates to the embodiment of the coupling points and consists in that the field electrodes 53a, 53b are insulated from the semiconductor layer 30 by an insulation 25a, 25b. The first insulator layer 20 and the second insulator layer 40 pass into one another in the area of the insulation 25a, 25b and insulate the field electrodes 53a, 53b with respect to the semiconductor layer 30. The first 20 and second 40 insulator layer and the insulations 25a, 25b can be constructed as one piece.

FIG. 4d shows a sectional view through the semiconductor substrate 10 in plane B3-B3′ in FIG. 4a. This view is identical to those from FIGS. 2d and 3d.

If the SOI semiconductor components according to an embodiment, presented in FIGS. 2a, 3a and 4a, are in the conducting state, a main current direction transverse to the field electrodes 53a, 53b and transverse to the field zones 13a, 13b, respectively, occurs in each case in their semiconductor layer 30 (see also sectional views 2c, 3c and 4c).

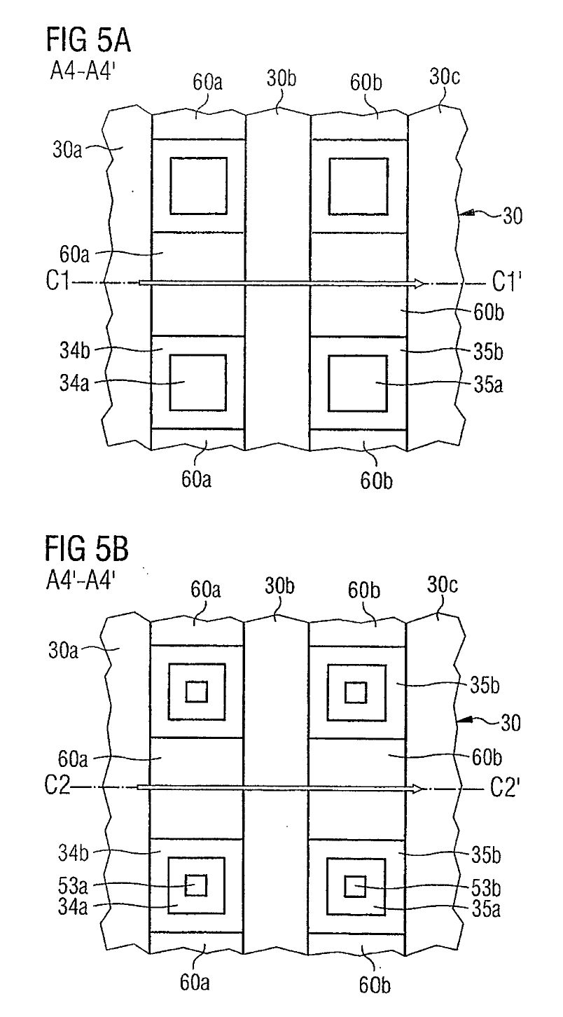

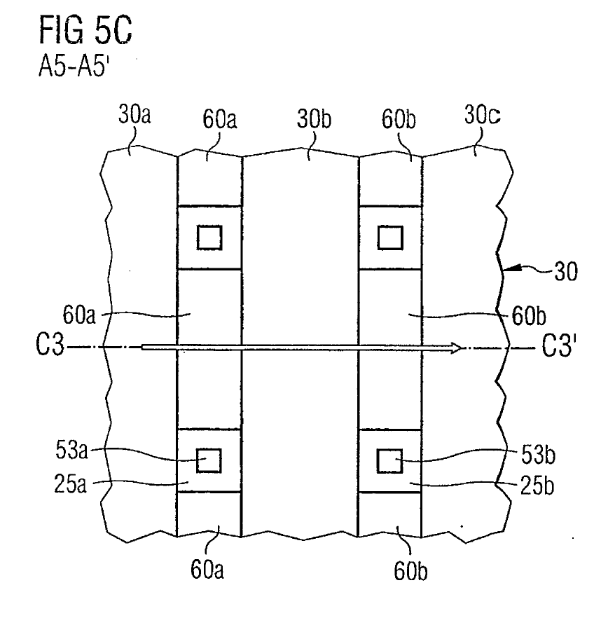

FIG. 5a corresponds to the representation from FIG. 2c but here two coupling points spaced apart from one another in the longitudinal direction of the field electrodes 53a, 53b are shown in each case. The main current direction is symbolized by the arrow drawn.

The cross section of the third semiconductor zone 30a, 30b, 30c, available for the current, is reduced in a direction transverse to the main current direction because the area of the third semiconductor zone 30a, 30b, 30c, which is recessed at the coupling points, is not available for a current flow. The consequence of this is an increase in the resistance of the drift zone. To compensate for this lack, it is advantageous, to raise the doping of the third semiconductor zone 30a, 30b, 30c between in each case two coupling points adjacent in a direction transverse to the main current direction in order thus to increase the number of charge carriers available for the current flow. In a particularly preferred embodiment, the doping is selected in such a manner that the number of free charge carriers between the first 31 and second 32 semiconductor zone is at least approximately constant in any direction transverse to the main current direction within the drift zone. The charge carriers lacking because of the coupling points are compensated for by increasing the doping. These areas with increased doping are correspondingly also called compensation zones 60a, 60b.

Analogously to FIG. 5a, FIGS. 5b and 5c correspond to FIGS. 3c and 4c, respectively. Here, too, two coupling points spaced apart from one another in the longitudinal direction of the field electrodes 53a, 53b are in each case shown. The main current direction is again symbolized by the arrows drawn.

Here, too, the cross section of the third semiconductor zone 30a, 30b, 30c available for the current in the main current direction is reduced because of the coupling points 53a/34a/34b, 53b/35a/35b and 53a/25a, 53b/25b. In order to compensate for the resultant increase in resistance, here, too, as in the SOI semiconductor component shown in FIG. 5a, compensation zones 60a, 60b are arranged in the third semiconductor zone 30a, 30b, 30c between coupling points 53a/34a/34b, 53b/35a/35b and 53a/25a, 53b/25b, respectively, which are spaced apart from one another transversely to the main current direction, in the SOI semiconductor components according to FIGS. 5b and 5c, which compensation zones have the same type of conduction as, but higher doping than, the third semiconductor zone 30a, 30b, 30c. This increases the number of charge carriers available for current conduction in the compensation zones 60a, 60b. The width of the compensation zones 60a, 60b in the SOI semiconductor components according to FIGS. 5a, 5b and 5c is in each case adapted to the dimensions of the coupling points 34a/34b, 35a/35b, 53a/34a/34b, 53b/35a/35band 53a/25a, 53b/25b in the main current direction.

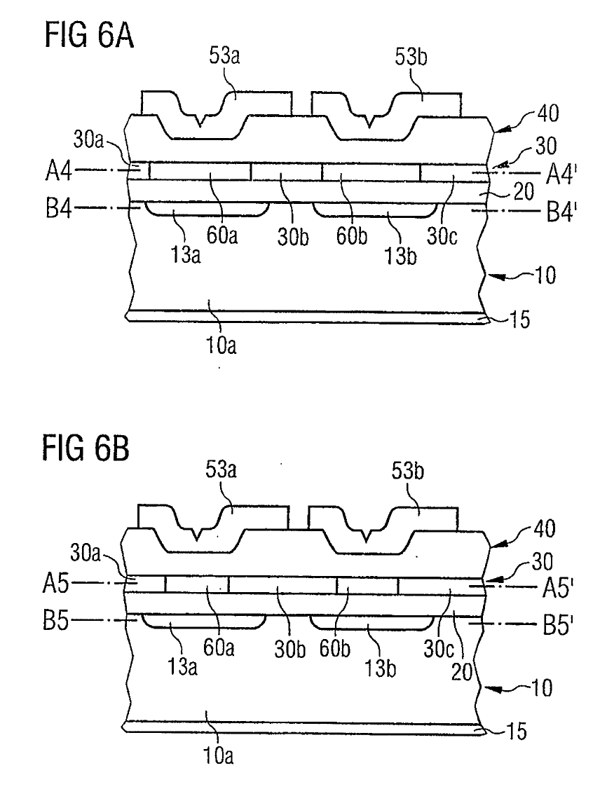

FIG. 6a shows a vertical section through an SOI semiconductor component according to FIGS. 5a and 5b in the area of the compensation zones 60a, 60b in a plane C1-C1′ and C2-C2′. Analogously, FIG. 6b shows a cross section through an SOI semiconductor component according to FIG. 5c in the area of the compensation zones 60a, 60b in a plane C3-C3′.

In comparison with the components shown in the two FIGS. 6a and 6b, it can be seen that the compensation zones 60a, 60b have different widths which depend on the doping concentration of the compensation zones 60a, 60b, the layer thicknesses of the second insulator layer 40 and the semiconductor layer 30, respectively, and the width of the field zones 13a, 13b, of the field electrodes 53a, 53b and of the coupling points 60a, 60b, i.e. of the first contacting zones 34a, 34b and the insulations 25a, 25b, respectively.

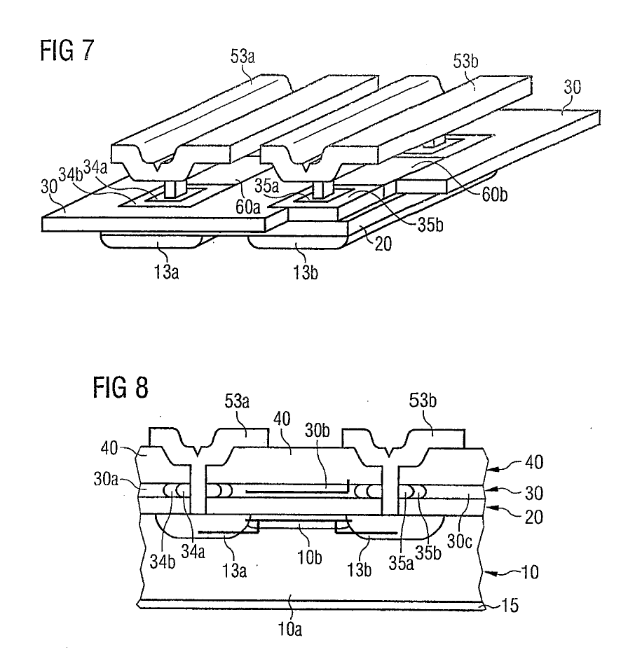

FIG. 7 shows a partially broken representation in an oblique view of an SOI semiconductor component according to an embodiment. The representation conforms to FIGS. 2 and 3. The second insulator layer 40 and the fourth semiconductor zone 10a are not shown for reasons of clarity.

A further aspect of an embodiment for increasing the reverse-voltage strength is directed to eliminating unwanted currents which arise in a parasitic MOS transistor. As shown in FIG. 8, such a parasitic MOS transistor is formed from the p-doped field zones 13a, 13b and the intermediate n⁻-doped area of the fourth semiconductor zone 10a acting as channel zone of the parasitic MOS transistor. The part 30b, opposite to this area, of the third semiconductor zone 30a, 30b, 30c arranged in the semiconductor layer 30 forms the gate of the parasitic p-MOS transistor. If the current in the semiconductor layer 30 rises, the parasitic p-MOS transistor is biased into conduction above a certain current intensity. The circuit diagram of the parasitic p-MOS transistor is also shown diagrammatically in FIG. 8.

To avoid a current flow via its parasitic MOS transistor, the doping of the fourth semiconductor zone 10a between the adjacent field zones 13a, 13b has been raised. This area is also called a channel stopper zone lob. In the exemplary embodiment shown, the channel stopper zone 10b extends along the boundary face between the semiconductor substrate 10 and the first insulator layer 20 starting from the field zone 13a to field zone 13b. Due to the channel stopper zone lob, the turn-on voltage of the parasitic p-MOS transistor is raised.

In the field electrodes 53a, 53b and in the field zones 13a, 13b, high potential differences can occur between the field electrodes 53a, 53b or the field zones 13a, 13b, respectively, and the third semiconductor zone 30a, 30b, 30c, mainly in the reverse state of the SOI semiconductor component. To avoid such high potential differences, it is provided to insert a zener diode structure between the field electrodes 53a, 53b and/or the field zones 13a, 13b and the third semiconductor zone 30a, 30b, 30c. A zener diode structure is understood to be an individual zener diode or a number of cascaded zener diodes.

Technically, a zener diode is implemented by a highly doped pn junction, i.e. by a transition from a p⁺-area to an n⁺-area. Such a zener diode structure has a particular threshold voltage. If a voltage applied to the zener diode structure from outside in the reverse direction exceeds this threshold voltage, the zener diode structure switches through, so that the voltage applied from outside is limited to the value of the threshold voltage.

The voltage present between a field electrode 53a, 53b or a field zone 13a, 13b, respectively, and the third semiconductor zone 30a, 30b, 30c can thus be limited to a permissible value by a suitably configured and interconnected zener diode structure.

In principle, it is possible to arrange the zener diode structure between a field electrode 53a, 53b or a field zone 13a, 13b, respectively, and the third semiconductor zone 30a, 30b, 30c at any point in the SOI semiconductor component, for example within the second insulator layer 40 or the first semiconductor layer 2. In a preferred embodiment, such zener diode structures are arranged at one or more, but not necessarily all coupling points of a field electrode 53a, 53b or a field zone 13a, 13b, respectively, within the semiconductor layer 30.

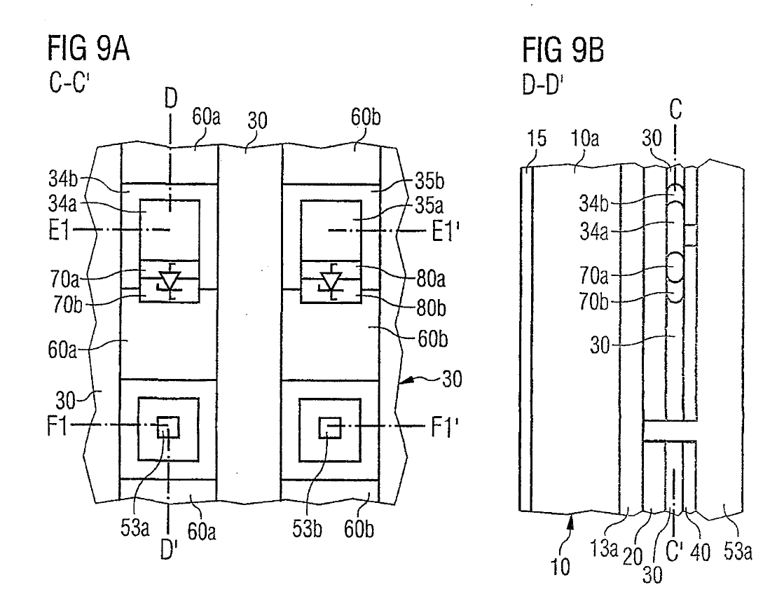

FIG. 9a shows an example of such an arrangement. The section through the semiconductor plane 30 shown here corresponds to the representation in FIG. 5b. In contrast, however, two of the coupling points were modified by the integration of a zener diode. In the two coupling points shown above, the p⁺-doped inner contacting zones 34a, 35a are in each case followed by a likewise p⁺-doped zener diode part-zone 70a, 80a followed by an n⁻-doped zener diode part-zone 70b, 80b. Together, the zener diode part-zones 70a and 70b and 80a and 80b, respectively, in each case form a zener diode 70 and 80, respectively.

The n⁺-doped zener diode part-zones 70b and 80b, respectively, are contacted with the third semiconductor zone 30a, 30b, 30c at the compensation zones 60a and 60b, on the one hand. On the other hand, the zener diode part-zones 70a, 80a are connected to the field electrodes 53a, 53b via the inner contacting zones 34a, 35a. Such an arrangement can be seen in FIG. 9b which shows a vertical section through two coupling points allocated to the same field electrode 53a. In this exemplary embodiment, the field electrode 53a is not electrically conductively connected to the field zone 13a at the coupling point provided with the zener diode 70. The zener diodes 70, 80 are exclusively arranged in the semiconductor plane 30.

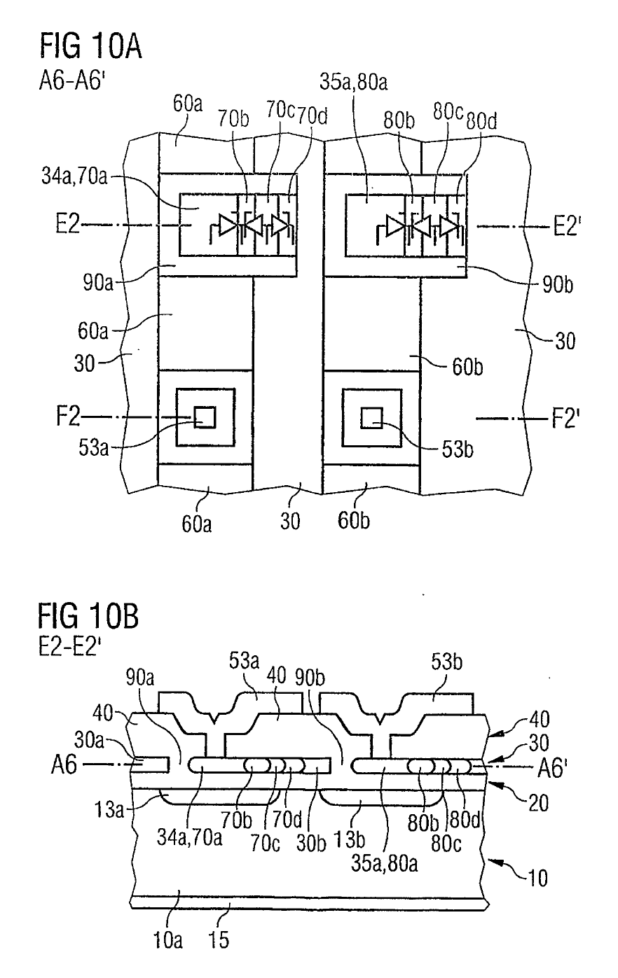

FIG. 10a shows a further example with zener diode structures 70, 80 arranged at coupling points. The SOI semiconductor component shown also corresponds to that from FIG. 5b. Here, too, one of the coupling points allocated to a field electrode 53a is provided with a zener diode structure 70. The zener diode structure 70 consists of a sequence of four zener diode part-zones 70a-d, immediately successive zener diode part-zones having a mutually complementary type of conduction.

Between the four zener diode part-zones 70a-d, there are three semiconductor junctions between adjacent, highly doped and mutually complementary zener diode part-zones. Each of these three junctions represents one of three cascaded zener diodes, the center zener diodes 70b/70c and 80b/80c, respectively, being oppositely polarized with respect to the outer zener diodes 70a/70b, 70c/70d, 80a/80b, 80c/80d.

The two identically structured zener diode structures 70, 80 are exclusively arranged in the semiconductor plane 30 and partially insulated with respect to the semiconductor layer 30 by insulations 90a, 90b. Only the zener diode part-zones 70d and 80d, arranged at one end of the zener diode structure 70, 80 are contacted with the third semiconductor zone 30a, 30b, 30c. The zener diode part-zones 70a, 80a located at the other end are p⁺-doped like the inner contacting zones 34a, 35a and constructed as one piece with these so that the zener diode structures 70, 80 are thus contacted with the field electrodes 53a, 53b.

FIG. 10b shows a section through plane E2-E2′ in the area of the zener diode structures 70, 80 according to FIG. 10a. It can be easily seen here, in combination with FIG. 10a, that the field electrode 53a and 53b, respectively, and the coupling points provided with a zener diode structure 70 and 80, respectively, are only contacted with the semiconductor layer via the zener diode structures 70 and 80, respectively. There is no contacting of the field electrode 53a and 53b, respectively, via an inner 34a and 35a, respectively, and an outer 34b and 35b, respectively, contacting zone in this exemplary embodiment.

In all SOI semiconductor components according to an embodiment, the channel stopper zones lob, if present, are of the same type of conduction as the semiconductor substrate 10, whereas the shield zones 11, 12, if present, and the field zones 13a, 13b have the other, complementary type of conduction. It is unimportant whether one type of conduction is n-conducting and the other one is p-conducting or conversely, the structure of the SOI semiconductor component otherwise being unchanged.

List of reference designations
10 Semiconductor substrate
10a Fourth semiconductor zone
10b Channel stopper zone
11, 12 Shield zone
13a, 13b Field zone
15 Substrate metallization
20 First insulator layer
25a, 25b Insulation
30 Semiconductor layer
30a, 30b, 30c Third semiconductor zone
31 First semiconductor zone
32 Second semiconductor zone
33 Fifth semiconductor zone/channel zone
34a, 34b First contacting zone
35a, 35b Second contacting zone
40 Second insulator layer
41 Gate electrode
51 Contact of the first semiconductor zone
52 Contact of the second semiconductor zone
53a, 53b Field electrode
60a, 60b Compensation zones
70, 80 Zener diode structure
70a, 70c, 80a, 80c Zener diode part-zone of the second type of conduction
70b, 70d, 80b, 80d Zener diode part-zone of the first type of conduction
90a, 90b Insulation of the zener diode structure

What is claimed is:

1. An SOI semiconductor component comprising a layered structure which successively comprises a semiconductor substrate, a first insulator layer and a semiconductor layer and further comprises:
a first semiconductor zone and a second semiconductor zone which are arranged laterally spaced apart from one another in the semiconductor layer, and a third semiconductor zone arranged between the first and second semiconductor zone,
a fourth semiconductor zone which is arranged in the semiconductor substrate,
at least one field zone which is arranged between the first and second semiconductor zone in the lateral direction in the semiconductor substrate and has complementary doping to the fourth semiconductor zone, and
at least one field electrode which is arranged between the first and second semiconductor zone in the lateral direction on the side of the semiconductor layer facing away from the first insulator layer.

2. An SOI semiconductor component according to claim 1, wherein the first semiconductor zone has the same type of conduction as the second semiconductor zone.

3. An SOI semiconductor component according to claim 1, wherein the first semiconductor zone has complementary doping to the second semiconductor zone.

4. An SOI semiconductor component according to claim 3, comprising a fifth semiconductor zone which has complementary doping to the first semiconductor zone and is arranged between the latter and the third semiconductor zone in the semiconductor layer.

5. An SOI semiconductor component according to claim 1, wherein the third semiconductor zone has the same type of conduction as the second semiconductor zone.

6. An SOI semiconductor component according to claim 1, wherein the first and/or the second semiconductor zone has higher doping than the third semiconductor zone.

7. An SOI semiconductor component according to claim 1, comprising an electrically conductive connection between the semiconductor substrate and the first and/or second semiconductor zone.

8. An SOI semiconductor component according to claim 1, wherein the semiconductor substrate has in the area of the electrically conductive connection between the first and/or second semiconductor zone, a first and second shield zone, respectively, with doping which is complementary to the fourth semiconductor zone.

9. An SOI semiconductor component according to claim 1, wherein at least one field electrode and at least one field zone are opposite one another with respect to the semiconductor layer.

10. An SOI semiconductor component according to claim 1, comprising at least one coupling point at which a field electrode is coupled to the semiconductor layer and/or a field zone in one of the following manners:
Type I: the field electrode is electrically conductively connected to the semiconductor layer but not to a field zone,
Type II: the field electrode is electrically conductively connected to the semiconductor layer and to a field zone, or
Type III: the field electrode is electrically conductively connected to a field zone but not to the semiconductor layer.

11. An SOI semiconductor component according to claim 10, comprising at least one coupling point of type I or II which has a contacting zone of the second type of conduction which electrically conductively connects the semiconductor layer to the at least one field electrode.

12. An SOI semiconductor component according to claim 11, wherein at least one contacting zone has a first area and a second area, wherein
the first area has higher doping than the second area,
the first area is contacted with the one field electrode, and
the second area is contacted with the semiconductor layer.

13. An SOI semiconductor component according to claim 10, comprising a coupling point of type III, at which the at least one field electrode is electrically insulated from the semiconductor layer.

14. An SOI semiconductor component according to claim 10, comprising at least one further coupling point of type I, II or III.

15. An SOI semiconductor component according to claim 14, wherein the third semiconductor zone has at least one compensation zone, arranged between two coupling points, in which the doping of the third semiconductor zone is raised.

16. An SOI semiconductor component according to claim 15, wherein the two coupling points, between which the compensation zone is arranged, are coupled to the same field electrode and/or the same field zone.

17. An SOI semiconductor component according to claim 1, wherein at least one of the field electrodes is constructed to be stepped.

18. An SOI semiconductor component according to claim 1, wherein the second semiconductor zone is electrically conductively connected to the second shield zone.

19. An SOI semiconductor component according to claim 1, comprising a channel stopper zone which
is arranged in the semiconductor substrate between a field zone and a further field zone or between a field zone and the first or second shield zone, and which has the same type of conduction as the fourth semiconductor zone but heavier doping than the latter.

20. An SOI semiconductor component according to claim 19, wherein the channel stopper zone is continuously formed from the at least one field zone to a further field zone or a shield zone, respectively.

21. An SOI semiconductor component according to claim 19, wherein the first and the second shield zone, the channel stopper zone and the field zones are arranged on the boundary face of the semiconductor substrate facing the semiconductor layer.

22. An SOI semiconductor component according to claim 1, comprising a zener diode structure having two terminal areas, one of the terminal areas being contacted with the third semiconductor zone and the other terminal area being contacted with the at least one field electrode or the at least one field zone, respectively.

23. An SOI semiconductor component according to claim 1, wherein the zener diode structure is arranged in the semiconductor layer.

24. An SOI semiconductor component according to claim 22, wherein the zener diode structure is arranged at a coupling point.

25. An SOI semiconductor component according to claim 22, wherein the zener diode structure has a number of cascaded zener diode junctions.

26. An SOI semiconductor component according to claim 22, wherein the zener diode structure is surrounded by an insulation area by area.

27. An SOI semiconductor component according to claim 1, wherein at least one field electrode is electrically insulated from the semiconductor layer.

28. An SOI semiconductor component according to claim 27, wherein at least one field electrode is electrically insulated from the semiconductor layer by a second, essentially layered insulator layer.

29. An SOI semiconductor component according to claim 1, wherein
the first type of conduction is n-conducting and the second type of conduction is p-conducting, or conversely,
the first type of conduction is p-conducting and the second type of conduction is n-conducting.

30. An SOI semiconductor component according to claim 29, wherein the fourth semiconductor zone is n-conducting or p-conducting.
